(19) United States
(12) Patent Application Publication
(10) Pub. No.: US 2011/0041016 A1
(43) Pub. Date: Feb. 17, 2011

(54) MEMORY ERRORS AND REDUNDANCY

(75) Inventor: Cormac Michael O'CONNELL, Ontario (CA)

Correspondence Address: Lowe Hauptman Ham & Berner, LLP (TSMC), 1700 Diagonal Road, Suite 300, Alexandria, VA, 22314, US

(73) Assignee: TAIWAN SEMICONDUCTOR MANUFACTURING COMPANY, LTD., Hsinchu (TW)

(21) Appl. No.: 12/849,157

(22) Filed: Aug. 3, 2010

Related U.S. Application Data
(60) Provisional application No. 61/233,387, filed on Aug. 12, 2009.

(51) Int. Cl. H03M 13/05; G06F 11/10

(52) U.S. Cl. 714/711; 714/763; 714/E11.034

(57) ABSTRACT

Redundancy including extra rows and/or columns of memory cells is added to the memory, and ECC parity is used to detect errors. When an error occurs at a location the first time, it is assumed to be a soft error, the data is corrected in this location, and the address of the erroneous cell (e.g., the failed address) is stored in a list. When another error occurs, it is determined whether its failed address is on the stored list. If it is not, then the error is again assumed to be a soft error, the data at this location is corrected, and the failed address is added to the stored address list, etc. If, however, the failed address is already in the stored failed address list, the error is considered either a latent error or VTR, and is repaired on the fly using on-chip redundancy.

### CROSS-REFERENCE TO RELATED APPLICATIONS

The present application claims priority of U.S. Provisional Patent Application Ser. No. 61/233,387, filed on Aug. 12, 2009 which is incorporated herein by reference in its entirety.

### FIELD

The present disclosure is generally related to memory errors. Various embodiments use ECC and redundant rows and columns to repair on the fly latent errors and VRT.

### BACKGROUND

Memory experiences different types of errors. Soft errors usually result from radiation from alpha particles in semiconductor package and neutron from the environment. VRT occurs when a bit some times acts as a weak bit (e.g., fail), and some times acts as a strong bit (e.g., pass), which may cause the device to pass final test (e.g., test before the device is shipped out of the chip manufacturer), but later intermittently fails. VRT behaves similar to soft errors except it usually recurs at the same address of the memory. Performance in semiconductor circuits can deteriorate over time due to electrical short between the gate-oxide and drains of transistors that causes a bit to be stuck at one level. This stuck-at error in a memory may cause latent failures wherein a device passes appropriate tests when it left the manufacturer but later (e.g., in another 5, 10 years) fails in the field. Soft errors happen randomly and are very unlikely to repeat in the same location multiples times while VRT and latent errors occur in the same location multiple times. Burn-in test can improve latent errors, but is expensive. When errors occur, some approaches related to CAM (content addressable memory) use shadow memory to redirect a memory access from internal DRAM to external SRAM, but shadow memory architecture can be expensive due to the extra circuitry and layout areas for that circuitry.

Error detections and corrections are commonly used in electronic circuits including networking systems. In Hemming code, if 32 bits are used then 6 extra bits are added for a single error correction and 7 extra bits are added for a single error correction and a double error detection. The extra bits may be referred to as ECC or parity bits.

### BRIEF DESCRIPTION OF THE DRAWINGS

The details of one or more embodiments are set forth in the accompanying drawings and the description below. Other features and advantages of the disclosure will be apparent from the description, drawings, and claims.

FIG. 1 shows an exemplary system upon which embodiments of the disclosure may be implemented.

FIG. 2 shows a first embodiment of the eDRAM in FIG. 1, illustrating a row-swap embodiment.

FIG. 3 shows a second embodiment of the eDRAM in FIG. 1, illustrating a word-swap embodiment.

FIG. 4 shows a third embodiment of the eDRAM in FIG. 1, illustrating a column-swap embodiment.

FIG. 5 shows a decision tree in accordance with an embodiment of the disclosure.

Like reference symbols in the various drawings indicate like elements.

### DETAILED DESCRIPTION

Some embodiments, or examples, of the disclosure illustrated in the drawings are described using specific language. It will nevertheless be understood that no limitation of the scope of the invention is thereby intended. Any alterations and modifications in the described embodiments, and any further applications of principles of the disclosure described in this document are contemplated as would normally occur to one skilled in the art to which the disclosure relates. Reference numbers may be repeated throughout the embodiments, but this does not necessarily require that feature(s) of one embodiment apply to another embodiment, even if they share the same reference number.

### Exemplary System

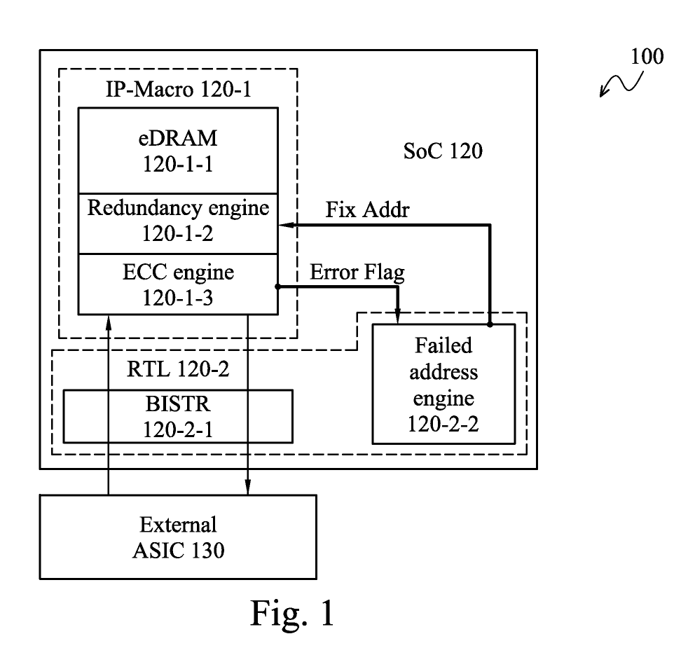

FIG. 1 shows an exemplary system 100 upon which embodiments of the disclosure may be implemented. System 100 includes a SoC (system-on-chip) 120, an ASIC (application specific integrated circuit) 130 external to SoC 120, and other circuitry including software, which, for simplicity, is not shown. In an embodiment, system 100 includes a network router or a network switch, but some embodiments of the disclosure are not limited to such an application, and are applicable to other systems. Depending on implementations, system 100 may be responsible for repairing an error or delegate it to other entities such as SoC 120, ASIC 130, etc. Further, system 100 may repair an error when the error is first identified or is scheduled to be repaired at another time as appropriate. Repairing an error includes overwriting the data with the data calculated and provided by ECC engine 120-1-3 or flipping the logic level of the existing data in the failed location.

SoC 120 represents a subsystem using eDRAM 120-1-1 that may have errors to be repaired. Generally, SoC 120 includes a complex electronic or computing system having sub systems integrated into a chip. Exemplary components of SoC 120 include a CPU (central processing unit), a data storage unit (e.g. memory), an IO controller, digital and/or analog circuitry, all of which are not shown. In an embodiment, SoC 120 includes a network package buffer, which stores, processes data packets, and provides them as appropriate. The term system or subsystem in this document includes, for example, a computing unit having intelligent capabilities (e.g., processing, computing, etc., capabilities).

IP-macro 120-1 generally includes a functional block, a subsystem, etc. In the embodiment of FIG. 1, because IP-macro 120-1 includes eDRAM 120-1-1 (e.g., a memory), IP-macro 120-1 may be referred to as a memory subsystem.

eDRAM 120-1-1 generally includes a plurality of banks of memory cells. Each bank includes a number of rows, a number of columns and related circuitry (e.g., sense amplifiers, word lines, bit lines), etc. Depending on applications, the size of eDRAM 120-1-1 varies, including, for example, 1, 2, 4 Mb, etc. A row of memory cell may be referred to as a word. Various embodiments of the disclosure provide mechanisms to repair on the fly errors (e.g., soft errors, latent errors, VRT, etc.) occurred in eDRAM 120-1-1. eDRAM 120-1-1 is a kind of memory used for illustration purposes, other storage devices including, for example, SRAM, flash, one time program (OTP), multi time program (MTP), etc., are within the scope of various embodiments. When appropriate, eDRAM 120-1-1 sends the data to ASIC 130 with parity bits.

Redundancy engine 120-1-2 is responsible for comparing addresses accessing eDRAM 120-1-1 with known faulty locations in that memory, in order to redirect those accesses to redundant or spare locations assigned to replace those known faulty memory areas. Normally at Final Test in production all redundant locations required are programmed and the parts are shipped. In various embodiments, a number of spare locations are reserved for a replacement that might be needed when a latent or VRT error is discovered in the field.

In various embodiments, redundancy engine 120-1-2 stores the address of the failed locations. When an error occurs in the field, for example, redundancy engine 120-1-2, based on the information provided by failed address engine 120-2-2, recognizes the failed location, controls and identifies the corresponding redundancy location used to repair that failed location. Once the failed location has been repaired and, when appropriate, redundancy engine 120-1-2 redirects an access to the failed location to a redundancy (repaired) location. Generally, when an error occurs, there may not be enough time to repair the error before the next access. In the case of a hard error, ECC engine 120-1-3 continues to cover the single bit error and protects the data until it is repaired. This allows time for discovery and repairing.

Depending on applications, an error in eDRAM 120-1-1 can be repaired in different ways. For example, if the data is static in eDRAM 120-1-1 for quite some time, redundancy engine 120-1-2 schedules for the repair (e.g., by ECC engine 120-1-3, by SoC 120, or by system 100, etc.) at a later time, but if the data is transient then the application itself overwrites the faulty location with fresh data, negating the need of an overwrite or correction. For example, in an application where eDRAM 120-1-1 is implemented as a circular FIFO input clock to output clock domain alignment, the application using the FIFO would write data into the faulty location before the next data access, in various embodiments, the application using the FIFO overwrites the data, which, in effect, repairs the erroneous data. As a result, the erroneous data is repaired without requiring any additional action.

Generally, ECC engine 120-1-3 encodes inbound data for storage and decodes and corrects outbound data when communicating with other circuitry (e.g., eDRAM 120-1-1, ASIC 130, etc.). ECC engine 120-1-3 recognizes the inbound data and adds necessary parity bits to the data. When eDRAM 120-1-1 is accessed, the data and associated parity bits are sent to ECC engine 120-1-3, based on which ECC engine 120-1-3 determines if there is any error. Generally, when an error occurs in eDRAM 120-1-1, ECC engine 120-1-3, based on the data and associated parity bits, recognizes an error arises, identifies the address of the failed bit, and flags that error. In an embodiment, ECC engine 120-1-3 uses six parity bits to correct a single error in a data word of 32 bits and seven parity bits to correct a single error and detect a double error. In various embodiments, ECC engine 120-1-3 can be defined by the SoC designer, and therefore suitable for use with different data width of a design choice, which is advantageous over other approaches where the ECC engine is limited to a data width when embedded in a memory block instance. This flexibility makes some embodiments of the disclosure more compatible with designing and supplying memory compilers and is general in the industry. Various embodiments of the disclosure use an ECC engine 120-1-3 known in the art.

RTL 120-2, known in the art, generally includes standard ASIC cells implemented with various functional blocks. Generally, a customer generates RTL-120-2 while BISTR (built-in self test with redundancy) engine 120-2-1 is provided to the customer having a repair algorithm to repair the errors as appropriate. Depending on applications, BISTR engine 120-2-1 includes capabilities to capture and provide the failed address to be used by other entities (e.g., SoC 120, eDRAM 120-1-1, etc.). BISTR 120-2-1 also includes capabilities to repair failed locations. Depending on implementations, some embodiments, in conjunction with failed address engine 120-2-2, use the repair algorithm in BISTR engine 120-2-1 already existed in SoC 120 to capture various addresses passing by and thus identify the address to be repaired. Because some embodiments use existing circuitry in BISTR 120-2-1, some embodiments can save layout space.

Failed address engine 120-2-2, based on the history of failure (e.g., a list of stored failed addresses), determines the type of failures and the action to be taken. Because soft errors occur randomly and are unlikely to repeat in the same location multiple times, if an error occurs only once in a location (e.g., occurs the very first time in a location), failed address engine 120-2-2 considers it as a soft error. If the error, however, occurs more than once in the same location (e.g., the second, the third time, etc.), failed address engine 120-2-2 considers it as a latent error or a VRT. For illustration purposes latent or VRT errors are referred to as “hard errors.” In various embodiments, failed address engine 120-2-2 stores a list of failed addresses. When an error occurs, failed address engine 120-2-2 compares the failed address to the stored list of failed addresses. If there is not a match, failed address engine 120-2 assumes the error to be a soft error. If, however, there is a match, failed address engine 120-2-2 considers the error to be a hard error. Failed address engine 120-2-2, based on information provided by ECC engine 120-1-3, calculates the correct data in a failed location and provides that data to redundancy engine 120-1-2. When appropriate, failed address engine 120-2-2 sends a request to repair the failed address to redundancy engine 120-1-2, which can repair on the fly using spare redundancy. Depending on implementations various embodiments use a CAM (content-addressable memory) to implement failed address engine 120-2-2 or utilize the capturing and comparing function in BISTR engine 120-2-1 to be part of failed address engine 120-2-2 to determine the type of errors.

ASIC 130 generally includes a specific application design, which, in the embodiment of FIG. 1, includes an NPU (network processing unit). ASIC 130 may be considered the brain of system 100. In various embodiments, ASIC 130 monitors ECC flag, and recognizes whether data is correct or needs to be repaired. If a flag is detected (e.g., an error has been identified) ASIC 130 stores the flagged address (e.g., the address of the failed cell). ASIC 110, when recognizing data to be repaired, identifies the address and sends it to failed address engine 120-2-2. Depending on implementations, ASIC 130 could delay for the repair to occur so that system 100 may decide when is a good time for the error to be repaired. Depending on applications, SoC 120 may perform those functions.

### First Embodiment of eDRAM

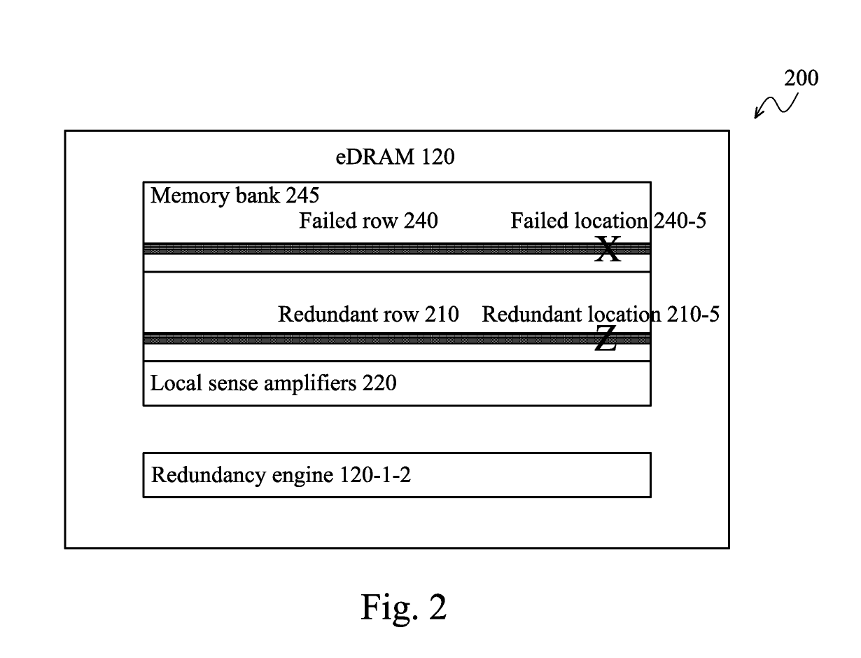

FIG. 2 shows eDRAM 200 illustrating a first embodiment of eDRAM 120-1-1. eDRAM 200 includes a plurality of memory banks, but, for illustration purposes, is shown having one memory bank 245 and redundancy engine 120-1-2.

Each memory bank of eDRAM 200 includes a plurality of rows and columns of memory cells, related circuitry, and a plurality of redundant rows 210 used to repair errors in eDRAM 200. The number of redundant rows 210 varies depending on applications and design choices, taking account of various factors including, for example, the expected life time of eDRAM 200, the estimated number of failures in that life time, etc. For illustration purposes, a row containing a failed cell 240-5 is referred to as a failed row, and memory bank 245 is shown having a failed row 240 and a redundant row 210 used to replace the failed row 240. Redundant row 210 includes a redundant location 210-5 corresponding to the failed location 240-5.

Before repairing a failed row 240 due to a “hard error,” redundancy engine 120-1-2 identifies a redundant row 210 to replace that failed row 240. Generally, eDRAM 200, via repair algorithms in BIST engine 120-2-1 or dedicated locations assigned in redundancy engine 120-1-2, receives from failed address engine 120-2-2 the failed address of location 240-5, which corresponds to a failed row 240 to be repaired. In an embodiment, redundancy engine 120-1-2 captures the data in the failed row 240 in local sense amplifier 220, and writes the corrected data through global write drivers in redundancy engine 120-1-2 into local sense amplifiers 220. Redundancy engine 120-1-2 then activates redundant row 210 that replaces the failed row 240 and writes data from the local sense amplifiers 220 into the redundant row 210. In an embodiment, memory cell data in the whole row 240 is transferred in parallel from the failed row 240 to the redundant row 210, which saves time as compared to transferring the data in series. Depending on applications, a word that contains the failed location 240-5, instead of a full row 240, is repaired, e.g., copied to the redundant row 210. Once the error has been completely repaired redundancy engine 120-1-2 re-directs future access to the failed address 240-5 in failed row 240 to the corresponding repaired address 210-5 in the redundant row 210. In an embodiment, failed address engine 120-2-2 programs the failed location 240-5 and corresponding redundant location 210-1 into a register of redundancy engine 120-1-2. When eDRAM 120-1-1 is accessed, the access address is checked against the register, and if there is a match then redundancy engine 120-1-2 redirects the access to the correct redundant location 210-1 stored in the register.

In various embodiments, the total sense amplifiers in the circuits are split between the top and the bottom of a bank and they share a global bit line. Depending on applications, data cannot be transferred from the erroneous row to the redundant row in one cycle, but may take 2 or more cycles.

In some embodiments, it takes one or two NOP instructions to repair the error, e.g., swapping a row including the erroneous bit. As a result, disruption to system operation is minimum in those embodiments.

### Second Embodiment of eDRAM

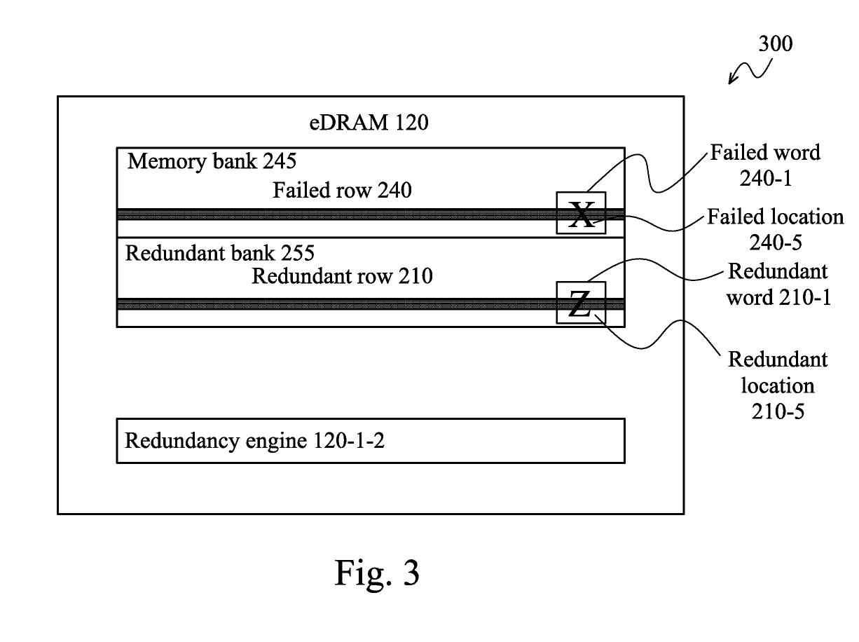

FIG. 3 shows an eDRAM 300 as a second embodiment of eDRAM 120-1-1. In this embodiment, as compared to eDRAM 200 each memory bank (e.g., memory bank 245) does not include redundant rows 210. Redundant rows 210 in eDRAM 300, however, are included in a separate redundant bank, e.g., redundant bank 255. The number of redundant banks 255 and the number of redundant rows 210 in a redundant bank 255 provided by various embodiments varies depending on applications and design choices, taking account of various factors including, for example, the expected life time of eDRAM 400, the estimated number of failures in that life time, etc.

In some embodiments, various memory banks 245 including redundant banks 255 are connected via global bit lines or global data lines, which also connect outputs of local sense amplifiers (e.g., local sense amplifiers 220 in FIG. 2) to a global sense amplifier (not shown). Based on information provided by ECC engine 120-1-3 redundancy engine 120-1-2 can identify the failed location 240-5 and/or failed word 240-1 based on which redundancy engine 120-1-2 can take appropriate action including flipping the failed data in failed location 240-5, using the global bit line. For example, failed address engine 120-1-2 uses the data provided by ECC engine 120-1-3 to create the correct word data and writes that data into redundant word 210-1

In an embodiment, redundancy engine 120-1-2 programs the failed row 240 to be repaired and copied data in the failed word 240-1 to the corresponding redundant word 210-1. Depending on applications, redundancy engine 120-1-2 can schedule a write to enter the corrected data to the redundant location 210-5 or queue a delayed write to the next quiet cycle, which may not require a NOP operation. Depending on applications, redundancy engine 120-1-2 writes corrected data in the failed location 240-5 to the redundant location 210-5 on the next free cycle.

Once the failed word 240-1 including the failed location 240-5 is completely repaired, redundancy engine 120-1-2 redirects a data access to the failed location 240-5 to the correct redundant location 210-5.

Some embodiments in FIG. 3 are advantageous because a redundant row 210 in a redundant bank 245 can be used to repair a failed location 240-5 and/or a failed word 240-1 in different memory banks.

### Third Embodiment of eDRAM

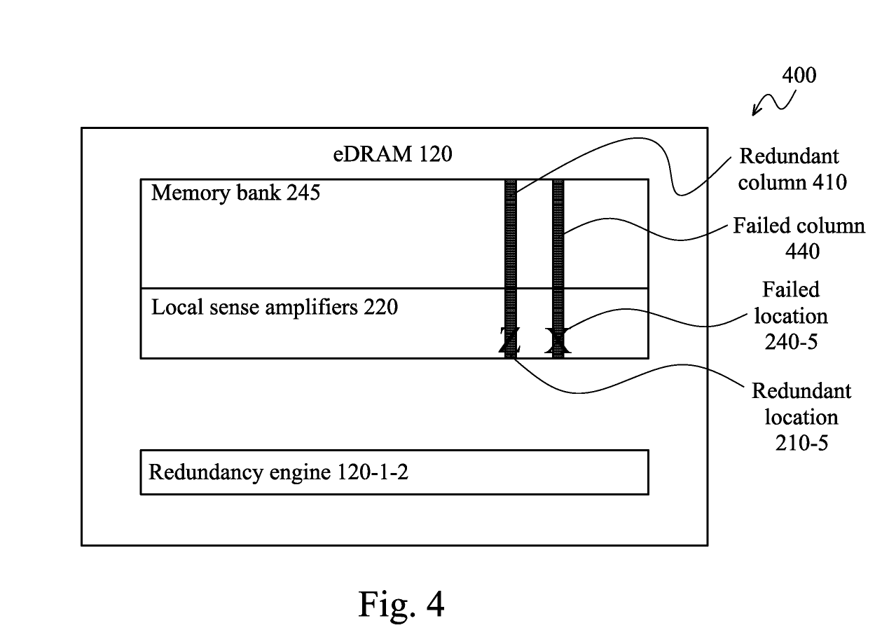

FIG. 4 shows an eDRAM 400 as a third embodiment of eDRAM 120-1-1. eDRAM 400, as compared to eDRAM 200 or 300, includes a plurality of redundant cells and associated circuitry such as bit lines, sense amplifiers, etc., used to repair an error on a bit line and/or bit-line sense amplifier area. For illustration purposes, a column including the failed location 240-5 is referred to as a failed column 440, and memory bank 245 is shown having a failed column 440 and a redundant column 410, which includes a redundant location 210-5 corresponding to the failed location 240-5. The number of redundant columns 410 provided by various embodiments varies depending on applications and design choices, taking account of various factors, including, for example, the expected life time of eDRAM 400, the estimated number of failures in that life time, etc.

In this example, a hard error is found at a sense amplifier, which affects the whole cells in failed column 440. Redundancy engine 120-1-2 swaps each cell in the failed column 440 for each cell in a redundant column 410. Once the failed column 440 has been replaced by the redundant column (e.g., memory cells, sense amplifiers, etc.), all cells in the redundant column 410 are written with the correct appropriate data. Depending on applications, various embodiments treat those redundant cells as having soft errors and correct them as correcting soft errors consistent with the spirit of various embodiments. For example, when there is an access to a cell in the redundant column 410, ECC engine 120-1-3 detects an error, and because this is a first error in that location, ECC engine 120-12 treats and corrects it as a soft error as appropriate. Alternatively, redundancy engine 120-1-2 schedules to write the correct data in the redundant column 410. For example, redundancy engine 120-1-2 waits for some quiet cycles or requests for NOP instructions (e.g., from system 100, from SoC 120, from ASIC 130, etc.) to have the data written. If, for example, there are 128 cells in a redundant column 410, redundancy engine 120-1-2 writes to 128 cells (e.g., 128 times), and if there are 256 cells, redundancy engine 120-1-2 writes 256 cells, etc.

### Exemplary Decision Tree

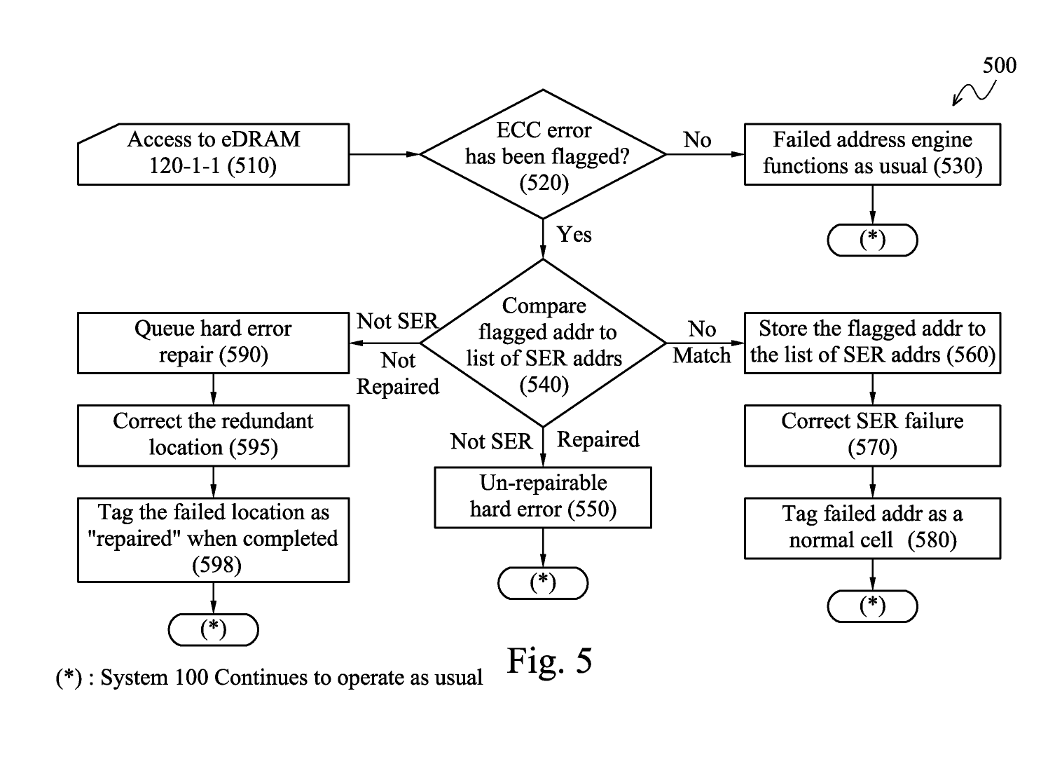

FIG. 5 shows a decision tree 500, in accordance with an embodiment of the disclosure. Depending on applications, decision tree 500 may be implemented in a finite state machine, including, for example, hardware logic running on a processor with software, etc. Decision tree 500 may be placed at different locations such as system 100, SoC 120, ASIC 130, etc. In this illustration, decision tree 500 is implemented in failed address engine 120-2-2.

In block 510, eDRAM 120-1-1 is accessed. In the meantime ECC engine 120-1-3 monitors for an error. If an error occurs failed address engine 120-2-2 captures the failed address indicated by the error flag caused by an ECC error.

In block 520, failed address engine 120-2-2 determines if ECC engine 120-1-3 has flagged an error. If ECC engine 120-1-3 has not flagged an error, failed address engine 120-2-2 100 in block 530 functions as usual, and system 100 continues to operate normally.

If, however, ECC engine 120-1-3 has flagged an error, and therefore captured the failed address of failed location 240-5, failed address engine 120-2-2 in block 540, receiving the failed address location 240-5 from ECC engine 120-1, compares the failed address location 240-5 to a list of previously failed addresses, which in effect, includes the list of soft error (e.g., SER) addresses.

If there is not a match (e.g., the failed address location 240-5 is not in the stored list of SER addresses), failed address engine 120-2-2, recognizing this is a new failure location, considers the error as a soft error, and, in block 560, stores this failed address location 240-5 in the stored list of SER addresses.

Failed address engine 120-2-2 in block 570 corrects the SER failure. Depending on applications, failed address engine 120-2-2 queues for this failed SER location 240-5 to be overwritten with the correct data. Alternatively, failed address engine 120-2-2 uses the corrected data and the failed location 240-5 provided by ECC engine 120-2-3 to flip the erroneous data currently stored in the failed location 240-5. In various embodiments, failed address engine 120-2-2 allows the application using eDRAM 120-1-1 to overwrite the failed location. This is generally done if failed address engine 120-2-2 recognizes that data would be overwritten before the next read access. Overwriting the failed location is, by definition, repairing the error.

In block 580, once the failed location 240-5 has been completely repaired (e.g., written with corrected data) failed address engine 120-2-2 tags the failed address location 240-5 to indicate that the failure has been repaired, and the failed location 240-5 is considered a normal functional cell.

At the decision block 540 if, however, there is a match, e.g., the failed address 240-5 is in the stored list of failed addresses, failed address engine 120-2-2 recognizes that this is not a soft error, but rather a hard failure because the failure occurs at least twice in the same location 240-5.

If the hard error has not been repaired, failed address engine 120-2-2 in block 590 queues for redundancy engine 120-1-2 to repair the hard error. Depending on situations, failed address engine 120-2-2 in conjunction with redundancy engine 120-1-2 identifies a redundant row 210 to replace the failed row 240, identifies a redundant word 210-1 to replace the failed word 240-1, or identifies a redundant column 410 to replace the failed column 440.

In various embodiments, once the redundant row 210, the redundant word 210-1, or the redundant column 410, has been identified, the redundant location 210-5 does not necessarily include the correct data. Failed address engine 120-2-2 in block 595 corrects the data in redundant location 210-5. Depending on applications, redundancy engine 120-1-2 queues for an overwrite of the redundant location 210-5 or redundancy engine 120-1-2 overwrites the data in redundant location 210-5 as appropriate. In the case of column swapping in FIG. 400, redundancy engine 120-1-2 overwrites all cells in redundant column 410. Alternatively, redundancy engine 120-1-2 uses the corrected data and the address of failed location 240-5 provided by ECC engine 120-1-3 to flip the logic state of the data in redundant location 210-5.

Once redundant location 210-5 is written with the corrected data, i.e., the error has been completely repaired, failed address engine 120-2-2 in block 598 tags the failed location 240-5 as completely repaired.

At the decision block 540, if, however, the failed location 240-5 is not a soft error, has been repaired once and now experiences failure again, system 100 in block 550 considers it as un-repairable, and continues to function as normal.

Some embodiments of the disclosure are advantageous over other approaches because error handling and/or repairing may be contained in a subsystem (e.g., SoC 120, ASIC 130, system 100, etc.), does not require handshaking, are invisible to other circuitry (e.g., ASIC 130, system 100), and may be referred to as a single chip solution. For example, in the embodiment of FIG. 1 where SoC 120 is responsible for error handling, redundancy engine 120-1-2, ECC engine 120-1-3, and failed address engine 120-2-2, are all included in a single SoC 120, system 100 does not require error handshaking between SoC 120 and ASIC 130, and may not even recognize if an error has occurred and/or repaired.

A number of embodiments have been described. It will nevertheless be understood that various modifications may be made without departing from the spirit and scope of the invention. For example, FIG. 1 shows ECC engine 120-1-3 in IP-macro 120-1 for illustration, ECC engine 120-1-3 could be implemented at different locations, e.g., in RTL 120-2, in ASIC 130, etc. Selecting a location for ECC engine 120-1-3 is a matter of design choice, customer preferences, etc., and some embodiments are not limited to any location for ECC engine 120-1-3. Failed address engine 120-2-2 could be independent of RTL 120-2, i.e., outside of RTL 120-2, in SoC 120, in ASIC 130, etc. Various embodiments of the disclosure are not limited to any location for failed address engine 120-2-2. In the illustrative embodiments, system 100, SoC 120, ASIC 130, failed address engine 120-2-2 are illustrated with some functions (e.g., responsible for repairing the errors, scheduling the errors, issuing the NOP instruction, etc.), but those functions may be performed interchangeably by other circuitry, and various embodiments are not limited to any particular function for any particular circuitry, etc. When appropriate SoC 120, instead of system 100 or ASIC 130, can schedule for the failed address in eDRAM 120-1-1 to be repaired.

Various method examples were described with exemplary steps, but performing them does not necessarily require the order as explained. Steps may be added, replaced, changed order, and/or eliminated as appropriate, in accordance with the spirit and scope of various embodiments.

What is claimed is:

1. A method comprising:
capturing an address of a failed location in a memory;
based on the address, determining an error type;
if the error type does not include a soft error, using redundancy to repair the error.

2. The method of claim 1 wherein determining the error type comprises comparing the address of the failed location to a list of addresses.

3. The method of claim 1, further comprising overwriting the failed location before a next access to the failed location, if the error type includes the soft error.

4. The method of claim 3 wherein overwriting the failed location is done by an application using the memory or by a system using the memory arranging the overwriting.

5. The method of claim 1 further comprising overwriting the failed location with correct data, if the error type includes the soft error.

6. The method of claim 1 further comprising storing the address to a list if the error type includes the soft error.

7. The method of claim 1 wherein using redundancy comprises one or a combination of providing at least one redundant row of memory cells in a memory bank, providing at least one redundant row of memory cells in a redundant bank, and providing at least one redundant column of memory cells and associated column circuitry.

8. The method of claim 1 wherein using redundancy comprises replacing a row containing the failed location for a redundant row.

9. The method of claim 8 wherein the row containing the failed location and the redundant row are in a same bank.

10. The method of claim 1 wherein using redundancy comprises replacing a word containing the failed location for a redundant word.

11. The method of claim 10 wherein the word containing the failed location is in a same bank with the redundant word.

12. The method of claim 10 wherein the word containing the failed location is in a bank different from a bank containing the redundant word.

13. The method of claim 1 wherein using redundancy comprises replacing a column of memory cells and associated circuitry containing the failed location for a redundant column of memory cells and associated circuitry.

14. The method of claim 1 wherein using redundancy to repair the error is performed on the fly.

15. A method comprising:
detecting an error at a memory location;
identifying the error as a soft error, and adding an address of the memory location to a list if the error occurs at the memory location the first time; and;
using a redundant location to replace the memory location if the error occurs at the memory location at least twice.

16. The method of claim 15 further comprising providing at least one redundant row in a same memory bank with the memory location.

17. The method of claim 16 wherein using a redundant location to replace the memory location comprises:
corresponding a row containing the memory location with a redundant row containing the redundant location;
copying data from the row containing the memory location to the redundant row;
writing correct data to the redundant location; and
redirecting access to the redundant location when accessing the memory location.

18. The method of claim 16 wherein using a redundant location to replace the memory location comprises:
corresponding a word containing the memory location with a redundant word containing the redundant location;
copying data from the word containing the memory location to the redundant word;
writing correct data to the redundant location; and
redirecting access to the redundant location when accessing the memory location.

19. The method of claim 15 further comprising:
providing at least one redundant row in a redundant bank separate from a memory bank of the memory location; and
using a redundant location to replace the memory location comprising:
corresponding a word containing the memory location with a redundant word containing the redundant location;
copying data from the word containing the memory location to the redundant word;
writing correct data to the redundant location; and
redirecting access to the redundant location when accessing the memory location.

20. The method of claim 15 further comprising:
providing at least one redundant column; and
using a redundant location to replace the memory location comprising:
corresponding a column containing the memory location with a redundant column containing the redundant location;
copying data from the column containing the memory location to the redundant column;
writing correct data to the redundant location; and
redirecting access to the redundant location when accessing the memory location.

21. The method of claim 20 wherein writing correct data to the redundant location comprises identifying data in the redundant location as corresponding to a soft error.

22. The method of claim 15 wherein determining if the error occurs at the memory location at least twice is based on the address of the memory location and the list.

23. The method of claim 15, further comprising executing a method selected from a group consisting of 1) having an application using the memory overwrite the memory location before a read access 2) having a processing unit using the memory arrange overwriting the memory location before a read access, and 3) overwriting the memory location, if the error is identified as the soft error.

24. The method of claim 15 wherein using redundancy to replace the memory location is done on the fly.

25. A method comprising:
capturing an address of a failed location in memory;
performing a soft error correction if the address is not in a list of soft error addresses; and
performing a hard error correction if the address is in a list of soft error addresses;
wherein the soft error correction comprises:
adding the address to the list;
repairing the failed location by a method selected from a group consisting of
using an application that uses the memory to overwrite the failed location before an access to the failed location;
using a processing unit that uses the memory to arrange an overwrite to the failed location before the access to the failed location; and
overwriting the failed location; and
the hard error correction comprises:
repairing the failed location by a method selected from a group consisting of
using a redundant row to replace a row containing the failed location;
using a redundant word to replace a word containing the failed location; and
using a redundant column to replace a column containing the failed location.

26. The method of claim 25 wherein the redundant row is in a same bank with the row containing the failed location when using a redundant row to replace a row containing the failed location.

27. The method of claim 25 wherein the redundant row is in a same memory bank with the row containing the failed location when using a redundant word to replace a word containing the failed location.

28. The method of claim 25 wherein the redundant row is in a bank separate from a bank containing the failed location when using a redundant word to replace a word containing the failed location.
